(19) United States
(12) Patent Application Publication
(10) Pub. No.: US 2026/0206239 A1
(43) Pub. Date: Jul. 16, 2026

(54) MANUFACTURABLE ULTRA-THIN STACKED COMPUTE AND MEMORY INTEGRATED CIRCUIT CUBE FOR HIGH BANDWIDTH AND CAPACITY

(71) Applicant: Mueon Corporation, Palo Alto, CA (US)

(72) Inventors: Jack HWANG, Palo Alto, CA (US); Wilfred Gomes, Palo Alto, CA (US)

(21) Appl. No.: 19/020,013

(22) Filed: Jan. 14, 2025

(51) Int. Cl. H10B 80/00; G06F 30/398; H01L 23/00; H01L 25/00; H01L 25/065; H01L 25/18

(52) U.S. Cl. CPC H10B 80/00; G06F 30/398; H10W 90/00; H10W 80/312; H10W 80/327; H10W 90/297; H10W 90/792

(57) ABSTRACT

In an example, the present invention provides a semiconductor integrated circuit cube device. The device has an interposer substrate member comprising a backside and a front side. In an example, the device has a plurality of sub-cube devices, each of which comprises a silicon substrate and a plurality of logic circuits or a plurality of memory circuits. In an example, each of the plurality of sub-cubes is manufactured as a separate device. In an example, each of the sub-cube devices comprises a hybrid bondable material. In an example, each of the sub-cube devices comprises a plurality of micro TSV structures configured to provide electrical routing through on or more devices in each of the sub-cube devices.

### BACKGROUND OF INVENTION

Semiconductor technology has played a transformative role in the evolution of modern computing systems, serving as the foundation for innovations in electronics and computational devices. Such transformative journey began with the invention of the transistor in 1947 by William Shockley, John Bardeen, and Walter Brattain at Bell Laboratories. The transistor, a compact semiconductor device, replaced the bulky and inefficient vacuum tubes previously used in electronic circuits. It provided a means to amplify and switch electrical signals with unprecedented reliability and energy efficiency. The transistor marked the beginning of the solid-state electronics era and laid the groundwork for subsequent advancements in semiconductor technology.

In the late 1950s, Robert Noyce, a co-founder of Fairchild Semiconductor and later Intel Corporation, further revolutionized the field with the development of the integrated circuit (IC). Noyce's IC innovation enabled the combination of multiple transistors and other electronic components on a single silicon substrate, significantly reducing the size, cost, and power requirements of complex circuits. His development of the planar transistor process further enhanced the fabrication of ICs, allowing for precise and scalable production using photolithography and diffusion techniques. These contributions not only made electronics more accessible and affordable but also facilitated the rapid development of increasingly sophisticated electronic systems.

The advancements in semiconductor technology were guided in large part by the principle articulated by Gordon Moore, another Intel Corporation co-founder. In 1965, Moore observed that the number of transistors on a single chip tended to double approximately every two years, leading to exponential improvements in computational power and reductions in cost per function. This observation, widely known as Moore's Law, became a driving force in the semiconductor industry, fostering a cycle of innovation and progress that propelled computing technology into everyday applications.

Despite the enduring influence of Moore's Law, the industry has encountered significant challenges as transistor dimensions approach atomic scales. These challenges include physical limitations, such as quantum tunneling effects that hinder reliable operation at smaller scales, as well as thermal and energy constraints associated with densely packed transistors. Furthermore, the cost of developing and manufacturing semiconductor devices at nanometer scales has escalated dramatically, requiring highly specialized and resource-intensive lithographic technologies.

In the context of artificial intelligence (AI) and large language models (LLMs), which demand immense computational power for both training and inference tasks, these limitations have necessitated the exploration of new solutions. Conventional approaches to address these challenges include heterogeneous computing architectures that combine traditional central processing units (CPUs) with graphic processing units (GPUs), tensor processing units (TPUs), and dedicated AI accelerators; advanced parallelization techniques for distributed workloads; and the exploration of emerging technologies like quantum computing, optical computing, and neuromorphic systems. Although successful, numerous limitations continue to plague conventional approaches.

From the above, it is seen that there is a need for continual innovation to overcome existing limitations and enable the next generation of high-performance computing systems.

### SUMMARY OF INVENTION

According to the present invention, techniques for manufacturing a semiconductor cube comprising cubelets are provided. Each of the cubelets is a sub-cube comprising a plurality of bonded semiconductor chips. Each of the cubelets are configured to be stacked to form a large cube in an example. Merely by way of example, the invention can be applied to a variety of applications, such as artificial intelligence (e.g., inference and learning, datacenter, edge compute), computing, chemical and biological analysis, financial robotics, vehicles (e.g., automobile, air), analysis, energy, genetics, information technology, datacenters, edge computing, telecommunication, and others.

In an example, the present invention provides a semiconductor integrated circuit cube device. The device has an interposer substrate member comprising a backside and a front side. In an example, the device has a plurality of sub-cube device comprising a silicon substrate and a plurality of logic circuits or a plurality of memory circuits. In an example, each of the plurality of sub-cubes is manufactured as a separate device. In an example, each of the sub-cube devices comprises a hybrid bondable material. In an example, each of the sub-cube devices comprises a plurality of micro TSV structures configured to provide electrical routing through on or more devices in each of the sub-cube devices. In an example, each of the plurality of micro-TSV structure has a dimension of about 2 microns and less. In an example, the device has a stacked configuration comprising the plurality of sub-cubes and configured such the hybrid bondable material from an underling sub-cube device is bonded to a topside of the silicon substrate of an overlying sub-cube device. In an example, the device has a bonding region configured between the front side of the interposer substrate and a backside of a bottom sub-cube device.

Depending upon the example, the present invention can achieve one or more of these benefits and/or advantages. In an example, the present invention provides a packaged semiconductor device configured in a high-density architecture that is a spatially efficient system and has related methods. In an example, the present invention offers advantages of a more compact semiconductor integrated circuit through an efficient size, weight, and cost using the present technologies. In an example, the technique provides for greater than ten times a number of conventional connections (e.g., 10,000) between a processor (e.g., CPU, GPU) to memory interface in conventional devices. In an example, the present device provides for higher memory bandwidth (e.g., eight time and greater) at lower power, e.g., greater than ⅕ of conventional devices. In an example, the number of connections is configured using a smaller portion (e.g., less than 10% of silicon as compared with conventional techniques for memory). These and other benefits and/or advantages are achievable with the present device and related methods. Further details of these benefits and/or advantages can be found throughout the present specification and more particularly below.

A further understanding of the nature and advantages of the invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1 illustrates scaling of peak hardware flops and memory/interconnect bandwidth (Gholami et al., IEEE 2023 hot chips, Ai and memory wall, IEEE Micro (Volume: 44, Issue: 3, May-June 2024)).

FIG. 2 illustrates a simplified layout of HBM (high bandwidth memory) and an area consumed by the through silicon vias (TSVs).

FIG. 3 is a simplified diagram of a Bumpless Build Cube “BBCUBE” (Chujo et al., Reference 1) in an example of the present invention.

FIG. 4 is a simplified diagram of a vertically stacked ultra-thin compute and memory with thermal heat spreader on compute according to an example of the present invention.

FIG. 5 is a simplified illustration of ultra-thinning a die that enables micro TSV's to reduce an area penalty of TSV's and enabling a higher density of connections in an example of the present invention.

FIG. 6 is a simplified example of how a memory design would be modified to take a low power double data rate (LPDDR) design to create eight times more input/output (I/O) density than a conventional LPDDR memory according to an example of the present invention.

FIG. 7 is a simplified illustration of an incoming wafer from the memory manufacturer with the completed capacitors and the first metal layers according to an example of the present invention.

FIG. 8 is a simplified illustration of a process flow for memory and compute cube fabrication according to an example of the present invention.

FIG. 9 is a simplified illustration of capacitive coupling that is a non-contact method of data transmission according to an example of the present invention.

FIG. 10 is a simplified illustration of an example of an interposer with an interconnect between a pair of die.

FIG. 11 is a simplified illustration of an example of a use of compute cubes for heterogeneous integration.

FIG. 12 is a simplified illustration of HBM superstacks by replacing each individual die with a cube of N (where Nis an integer) stacked memory die according to an example of the present invention.

### DETAILED DESCRIPTION OF THE EXAMPLES

The present invention provides advancements in semiconductor technology and, in particular, to various types of processing devices designed to specific computational tasks. The devices, integral to modern computing systems, are distinguished by their architectures and functionalities. In an example, the present invention provides for a manufacturable ultra-thin stacked compute plus memory to enable higher bandwidth, higher capacity memory, lower power, and preferably independently simultaneously addressable memory chips. Merely by way of example, the invention can be applied to a variety of applications, such as artificial intelligence (e.g., inference and learning, datacenter, edge compute), computing, chemical and biological analysis, financial robotics, vehicles (e.g., automobile, air), analysis, energy, genetics, information technology, datacenters, edge computing, telecommunication, and others.

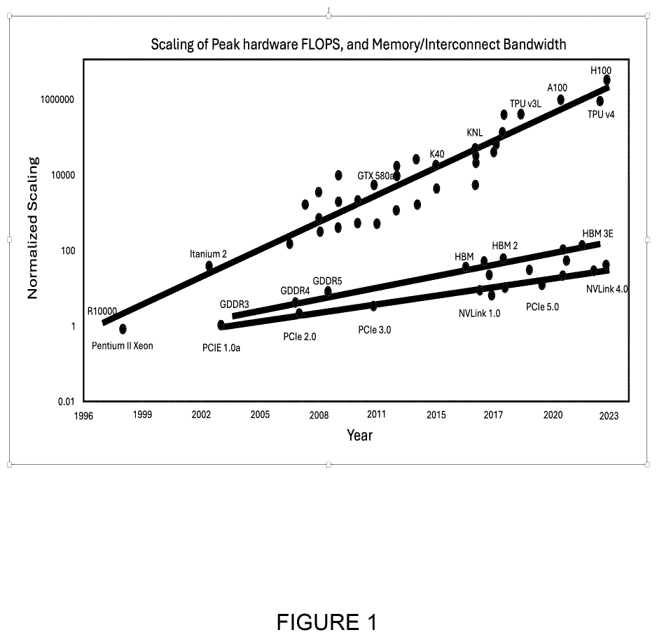

As background, floating point compute has been increasing at three times per two years while memory bandwidth has been increasing at one and a half times per two years. A widening gap has shifted the bottleneck for AI training from calculation to memory bandwidth. See, for example, FIG. 1.

FIG. 1 illustrates scaling of peak hardware flops and memory/interconnect bandwidth (Gholami et al., IEEE 2023 hot chips, AI and memory wall, IEEE Micro (Volume: 44, Issue: 3, May-June 2024)). In an example, high bandwidth memory (HBM) was created to close the gap compared to conventional DRAM for capacity and bandwidth. HBM is constructed by stacking N memory chips using thermal compression or hybrid bonding and TSV (through silicon vias) with a thin die with thickness of approximately 40 μm, limited by the mechanical strength of the die. For example, HBM third generation (3) is comprised of a stack of twelve memory die that is connected by TSV's through thermal compression bonding. For a typical TSV with a manufacturable aspect ratio of 8:1 (e.g., depth vs. diameter) for a 40 um thick die, the TSV will be approximately 5-6 μm in diameter. The large TSV's results in the structures taking approximately 20-30% of the die. While an improvement over DRAM for bandwidth and capacity, this is insufficient in the AI era.

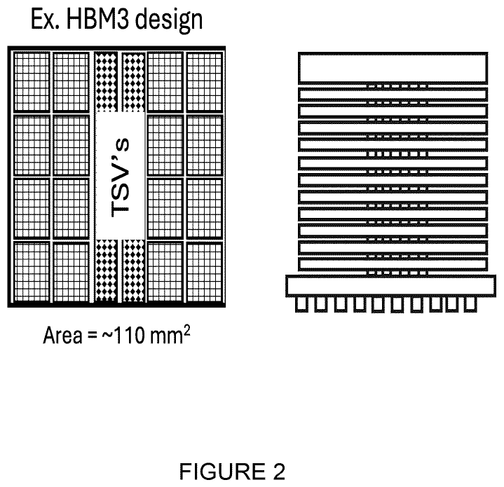

FIG. 2 illustrates a simplified layout of HBM and an area consumed by the TSV's. As shown, the HBM layout and three-dimensional structure with the central region dedicated to TSVs are illustrated. As shown, the region occupying the TSVs is twenty percent or more of the area of the silicon. For example, HBM3E is a twelve memory stack package assembled with thermal compression bonding. The memory stack is configured on an interposer substrate.

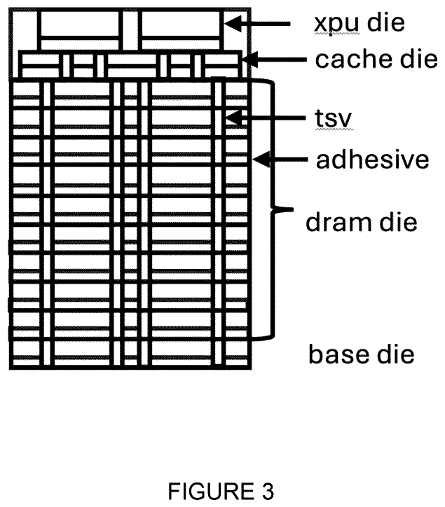

In an example, attempts to integrate compute and memory (e.g., Chujo et al. and See, FIG. 3), utilizes wafer to wafer bonding via adhesives to create a compute stack with silicon thinned to 10 um. The thinner die enables higher TSV density per unit area for higher bandwidth. They are able to achieve 1.6 TB/see memory bandwidth compared to 1.229 TB/see for HBM3E.

Various limitations exist with the afore-mentioned techniques. In an example, such limitations include yield. That is, the fabrication method is wafer to wafer. For a high yielding process (90%), the total yield of ten (10) die stack is 0.910 to about 30% yield as the entire stack requires all ten (10) die to yield. The limitations include cooling. In particular, glue separates the die and acts as an insulator so this method is limited. The limitations includes that only one die is addressable at a time as the TSV's (through silicon vias) are stacked. The limitations include the bandwidth gains, and in particular, incremental improvement over HBM3E, which is the conventional HBM version. The limitations include die thicknesses. That is, the non-uniformity of the glue process limits the die thinning due to the inherent non-uniformity of the process. Of course, other limitations can also exist depending upon the application.

FIG. 3 is a simplified diagram of a BBCUBE (Chujo et al., Reference 1) in an example of the present invention.

To overcome the conventional limitations, the present invention provides a cube device and related methods, as will be described throughout the present specification and more particularly below.

In an example, the present invention provides a semiconductor integrated circuit cube device. The device has an interposer substrate member comprising a backside and a front side. In an example, the device has a plurality of sub-cube device comprising a silicon substrate and a plurality of logic circuits or a plurality of memory circuits. In an example, each of the plurality of sub-cubes is manufactured as a separate device. In an example, each of the sub-cube devices comprises a hybrid bondable material. In an example, each of the sub-cube devices comprises a plurality of micro TSV structures configured to provide electrical routing through on or more devices in each of the sub-cube devices. In an example, each of the plurality of micro-TSV structure has a dimension of about 2 microns and less. In an example, the device has a stacked configuration comprising the plurality of sub-cubes and configured such the hybrid bondable material from an underling sub-cube device is bonded to a backside of the silicon substrate of an overlying sub-cube device. In an example, the device has a bonding region configured between the front side of the interposer substrate and a backside of a bottom sub-cube device.

As used herein, the term sub-cube can also be referred to at cubelet or cubelets.

In an example, the interposer substrate member is active or passive. In an example, each of the plurality of sub-cube devices has a thickness of 100 microns and less. In an example, each of the sub-cube devices comprises at least two upper conductive regions. In an example, each of the at least two upper conductive regions of each of the sub-cube devices is configured for an architecture design of the cube device.

In an example, each of the sub-cube devices comprises at least two upper conductive regions. In an example, each of the at least two upper conductive regions of each of the sub-cube devices is configured for an architecture design of the cube device. In an example, the architecture design is configured to allow independent communication from a processing device within one or more of the sub-cube devices to each of one of the plurality of memory devices in one or more of the sub-cube devices.

In an example, each of the plurality memory circuits 128 Gbit and greater. In an example, the plurality of logic circuits comprise, e.g., a 1000 cores and greater of GPU logic. In an example, the plurality of logic circuits comprise, e.g., 5 cores and greater of CPU logic. In an example, each of the sub-cubes comprises at least, e.g., 100,000 micro TSVs within two millimeter square or less. In an example, the bonding region is characterized by a hybrid bond between the interposer substrate and one of the plurality of sub-cube devices. In an example, each of the sub-cube devices has been tested using a probe card and are categorized as a good device. In an example, each of the sub-cube device is made using a 50-millimeter square of silicon and less. In an example, each of the sub-cube devices has been tested using a probe card and are categorized as a good device and provided from a yielded wafer of 80% and greater. In an example, the plurality of logic devices comprises at least a pair of the plurality of logic devices for redundancy. In an example, the plurality of memory devices comprises at least ten percent or more of the memory devices for redundancy. In an example, the interposer substrate comprises a plurality of cube sites for wafer scale processing.

In an example, the interposer substrate comprises a plurality of cube sites for wafer scale processing, and configuring a plurality of cube devices, respectively, for the plurality of cube sites. In an example, each of the sub-cube devices comprises at least three layers. In an example, the plurality of sub-cube devices comprises sixteen and greater sub-cube devices. In an example, each of the sub-cube devices comprises at least four layers and the plurality of sub-cube devices comprises twelve and greater sub-cube devices configured to stack forty-eight separate and independent integrated circuit devices.

In an example, the present invention provides a method for manufacturing an integrated circuit cube device. The method includes providing a first interposer substrate member comprising a backside and a front side. In an example, the method includes bonding a first sub-cube device to the front side of the first interposer substrate from a plurality of sub-cube devices numbered from 1 through N, where N is an integer greater than 2. In an example, the first sub-cube device comprises a first silicon substrate and a plurality of first logic circuits or a plurality of first memory circuits. In an example, the first sub-cube is manufactured as a separate device. In an example, the first sub-cube device comprises a first hybrid bondable material. The first sub-cube device comprises a plurality of first micro TSV structures configured to provide electrical routing through on or more devices in the first sub-cube devices. In an example, each of the plurality of first micro-TSV structure having a dimension of about 2 microns and less.

In an example, the method includes providing a second sub-cube device assembled onto a second interposer substrate. In an example, the second sub-cube device comprises a second silicon substrate and a plurality of second logic circuits or a plurality of second memory circuits. In an example, the second sub-cube is manufactured as a separate device. In an example, the second sub-cube device comprises a second hybrid bondable material. In an example, the second sub-cube device comprises a plurality of second micro TSV structures configured to provide electrical routing through on or more devices in the second sub-cube device. In an example, each of the plurality of second micro-TSV structure has a dimension of about 2 microns and less. In an example, the method includes assembling the second sub-cube device by coupling the second hybrid bondable material of the second sub-cube device to the first hybrid bondable material of the first-cube device.

In an example, the method includes providing a third sub-cube device assembled onto a third interposer substrate. In an example, the third sub-cube device comprises a third silicon substrate and a plurality of third logic circuits or a plurality of third memory circuits. In an example, the third sub-cube is manufactured as a separate device. In an example, the third sub-cube device comprises a third hybrid bondable material. In an example, the third sub-cube device comprises a plurality of third micro TSV structures configured to provide electrical routing through on or more devices in the third sub-cube device. In an example, each of the plurality of third micro-TSV structure has a dimension of about 2 microns and less. In an example, the method includes assembling the third sub-cube device by coupling the third hybrid bondable material of the third sub-cube device to the second hybrid bondable material of the second-cube device.

In an example, the method includes providing an Nth sub-cube device assembled onto an Nth interposer substrate. In an example, the Nth sub-cube device comprises an Nth silicon substrate and a plurality of Nth logic circuits or a plurality of Nth memory circuits. In an example, the Nth sub-cube being manufactured as a separate device. In an example, the Nth sub-cube device comprises a Nth hybrid bondable material. In an example, the Nth sub-cube device comprises a plurality of Nth micro TSV structures configured to provide electrical routing through on or more devices in the Nth sub-cube device. Each of the plurality of Nth micro-TSV structure has a dimension of about 2 microns and less. In an example, the method includes assembling the Nth sub-cube device by coupling the Nth hybrid bondable material of the Nth sub-cube device to the N−1 hybrid bondable material of the N-cube device. In an example, the method includes forming a thermally conductive material overlying an upper surface of the Nth sub-cube device.

In an example, the method includes subjecting the cube device to thermal treatment. In an example, the method includes forming an oxide material to fill one or more gaps between a pair of cube devices for mechanical stability. In an example, the method includes forming an oxide material to fill one or more gaps between a pair of cube devices for mechanical stability; and polishing an upper surface of the oxide material. In an example, the method includes separating the cube device using an oxygen rich plasma.

In an example, the invention provides a method for designing a semiconductor integrated circuit cube device. The method includes providing a target design file (e.g., Register Transfer Language (RTL)) associated with an integrated circuit cube device. In an example, the method includes configuring the target design file with one or more integrated circuit design files for a plurality of sub-cube device comprising a silicon substrate and a plurality of logic circuits or a plurality of memory circuits. In an example, each of the plurality of sub-cubes is manufactured as a separate device. In an example, each of the sub-cube devices comprises a hybrid bondable material. In an example, each of the sub-cube devices comprises a plurality of micro TSV structures configured to provide electrical routing through on or more devices in each of the sub-cube devices. In an example, each of the plurality of micro-TSV structure has a dimension of about 2 microns and less. In an example, the method includes outputting the target design file configured with the one or more integrated circuit design files to layout the integrated circuit cube device configured in a stacked configuration comprising the plurality of sub-cubes and configured such the hybrid bondable material from an underling sub-cube device is bonded to a backside of the silicon substrate of an overlying sub-cube device.

Further details of the present invention can be found throughout the present specification and more particularly below.

In an example, the present invention provides for chip stacking ultra-thin die (e.g., ~1-2 um silicon substrate pattern) of memory and compute with micro TSV's with, e.g., ten times the number of connections, compared to HBM will enable significantly more memory bandwidth, and lower power compared to the conventional art.

In an example, the present technique provides for a very large numbers of die (e.g., 12, 16, 20, 40 plus) can be stacked because more die can be stacked while remaining within the maximum height allowable by process tools. In an example, superstacks of die can be constructed by stacking stacks of known good die cubes (See, FIG. 3). In an example, as used herein, each cube-sub assembly is called a cubelet. Each cubelet can be a stack of individual integrated circuit devices, including a plurality of memory devices and/or logic devices, e.g., compute, processors.

In an example, the present cubelet can be used with conventional tools for assembling into a cube configured with a plurality of integrated circuit devices. That is, each cubelet can be used to replace a conventional semiconductor chip in conventional tools.

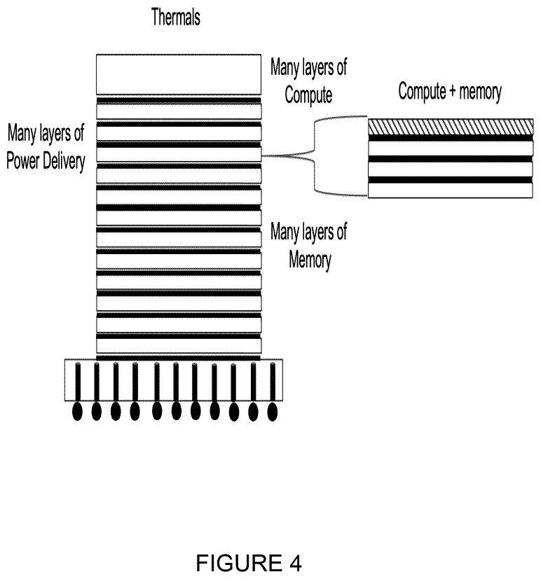

FIG. 4 is a simplified diagram of a vertically stacked ultra-thin compute and memory with thermal heat spreader on compute according to an example of the present invention. In an example, wafer to wafer stacking can be used limited by yield/die size. Creation of the ultra-large stacks can be created by stacking known good cubelets. In an example, the present technique includes ultra-thinning the silicon substrate to ~1 um enables an architecture with micro-TSV's to eliminate the area penalty and provides orders of magnitude more signal connections. In an example, each micro TSV is characterized by a diameter of about one micron and having a pitch of three to thirty microns in one or more examples.

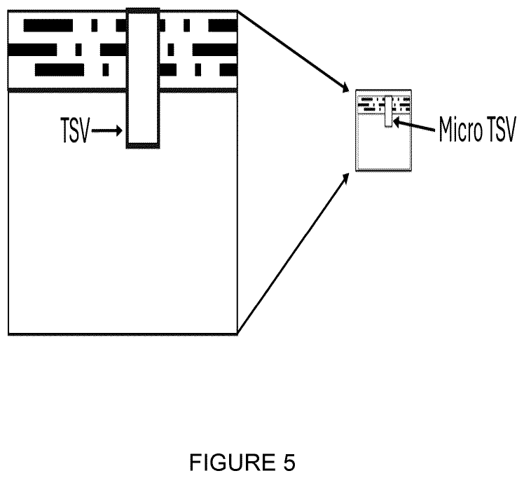

FIG. 5 is a simplified illustration of ultra-thinning a die that enables micro TSV's to reduce the area penalty of conventional TSV's and enabling a higher density of connections in an example of the present invention. In an example, the die is characterized by a manufacturable aspect ratio for TSV is approximately 8:1 (which can be greater or less) so if the substrate is thinned, e.g., to ~1 micrometer, and allowing, e.g., 6 um thickness, for the devices, a TSV of 1 um would have an aspect ratio, e.g., of 7:1. Compared to conventional TSV's in HBM that are ~7 μm and are approximately 50 mm deep, the process times is seven times faster (e.g., lower cost). Utilizing a 3 micrometer pitch for TSV's, one hundred thousand (100K) connections would be on order of 1 mm². This provides a, e.g., twenty to thirty times (20-30×) improvement over the TSV area in HBM while providing more than (10×) more signal connections. This enables various architecture features that are improved over conventional techniques.

In an example, the present technique includes micro TSV's enables high bandwidth and improved energy (pico-Joules)/bit for memory transfer according to an example of the present invention.

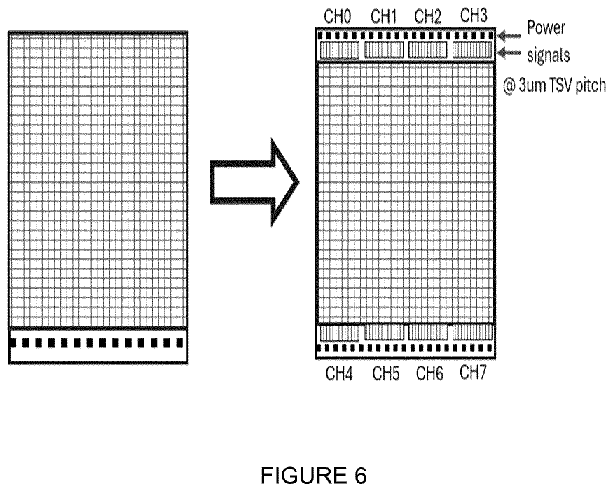

FIG. 6 is a simplified example an example of how a memory design would be modified to take an LPDDR design to create eight time (8×) more input/output (I/O) density than the conventional LPDDR memory according to an example of the present invention. As shown, a low power of LPDDR combined with eight times more bandwidth (thirty two times more connections, but four times slower bit transfer for lower energy) is a desirable solution to reduce the power/bit which is an important concern for AI architectures. This can be compensated for by increasing the number of connections by four times (4×). The high density of TSV connections can also provide for the compute die to address simultaneously all the memory die in the cube at once and/or independently address each memory cell independently from a processing device using separate communication channels configured between the cubelets.

As shown above in the diagram is an example of modifying a conventional LPDDR memory with sixteen pin communication lines to eight times channels with power distribution on both sides of the die. This can provide increased bandwidth, and lower power consumption, among other benefits.

In an example, the present technique provides a system architecture by having the foundry provide compute and memory wafers without, e.g., the last two metal layers. In an example, the present technique provides for a system foundry to add TSV mid, and the top two metal layers to provide the connectivity for the cube using an integrated cubelet. In an example, the technique removes a plurality of memory wafers mid process from a conventional DRAM facility once the first capacitors are formed and connected from the memory supplier. In an example, the memory wafers are configured into cubelets, which are configured to form a resulting cube. In an example, high density TSV's are configured into the memory device cubelets so the compute integrated circuit die can access each memory devices separately and independently using separate channels.

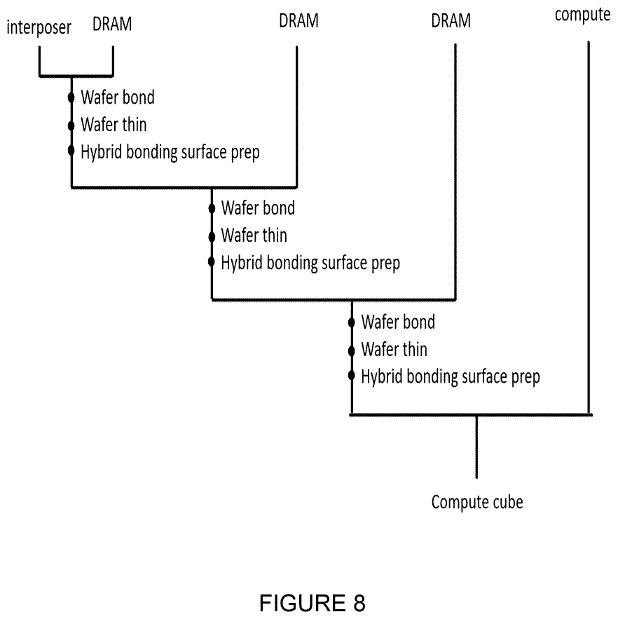

In an example, a technique would be to add TSV mid and add two metal layers for power delivery and signal routing. In addition, the surface layer would be prepared for hybrid bond interface. A similar procedure would take place for the compute die as referenced in FIG. 8.

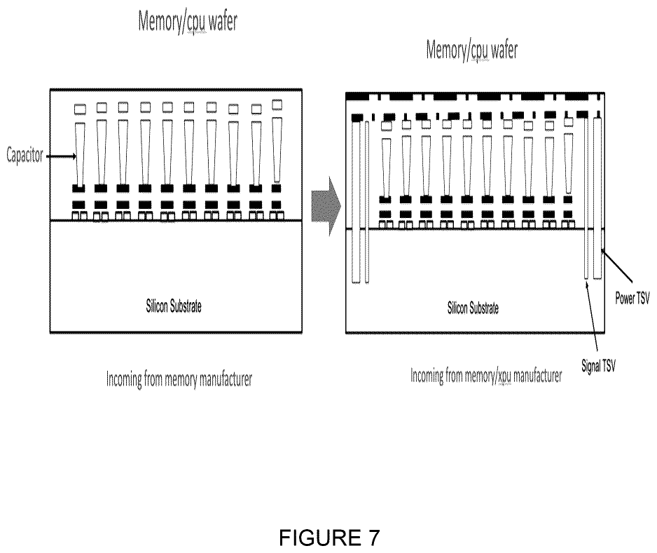

FIG. 7 is a simplified illustration of an incoming wafer from the memory manufacturer with the completed capacitors and the first metal layers according to an example of the present invention. In an example, the TSV's and upper metal layers would be added in addition to the hybrid bonding-interface, as shown.

In an example, the present technique provides for methods for the fabrication of high yielding compute and memory cube with ultra-thin die. In an example, as background, ultra-thin die can generally not be handled, temporary glues for carrier wafers are not uniform enough to support the ultra-thin wafers (e.g., ~1 um), chip to wafer hybrid bonding yields are challenging, and throughput is a major bottleneck for manufacturing, and wafer to wafer bonding by itself will not yield due to the stacking of defects, among other limitations.

In order to overcome the aforementioned limitations, the present technique includes a sequence of steps. In an example, the wafers will be sequentially hybrid bonded in a wafer to wafer process and thinned starting with an interposer wafer. The permanent bonded wafers have no glue (as conventional techniques) which solves the non-uniformity problem, and the interposer wafer provides the support. The ultra-thinning process has been demonstrated in the fabrication of backside power delivery processes from all of the major chip companies.

FIG. 8 is a simplified illustration of a process flow for memory and compute cube fabrication according to an example of the present invention. This cube can be used as the building block for larger systems. For compute on top, the last step is chip on wafer to the memory cube as one method. Another method utilizing wafer to wafer bonding will be discussed as an additional claim.

In an example, the present technique includes a die size that will be optimized or improved for yield. Using a wafer to wafer process for hybrid bonding is much preferred over chip to wafer attach which is a less mature technique. The throughput is greater than, e.g., 30 times better with wafer to wafer bonding. Using statistics, if four wafers are stacked together using a defect density of 0.1 defects/cm², a mature process technology, a 10×10 mm die will yield as shown in the Table depending on how much redundancy the design has MWA (i.e., must work area) (e.g., 0->100%). In the worst case of no redundancy, a 100 mm² die will yield 87%, and a four-stack memory die will yield 57%. A 5×5 die will yield 81%. Depending on the redundancy and the defect density, a desirable die size can be determined for the process. See also Table below.

In an example, the present technique includes attaching two logic wafers with wafer to wafer bonding, the yield for at least one of the die working is one method to avoid using chip to wafer bonding for the cube. For a 5×5 die, 4 memory die+2 logic die will have 81% working 4 memory die and at least one logic die for no redundancy. The sort process can separate the cubes into separate manufacturing bin for sale at different price points. With high redundancy, 84.6% of the cubes will be functional.

TABLE 1

| | | | 4 Stack | | |
|---|---|---|---|---|---|
| Die Size | Yield | Yield Loss | Yield | 4 + 1 | 4 + 1&1 |
| MWA 10% | | | | | |
| 10 × 10 mm | 94.6 | 5.4 | 80 | 75.7 | 79.8 |
| 7 × 7 mm | 95.9 | 4.1 | 84.7 | 81.3 | 84.6 |
| 5 × 5 mm | 96.9 | 3.1 | 88.3 | 85.6 | 88.2 |
| MWA 100% | | | | | |
| 10 × 10 mm | 87.2 | 12.8 | 57.8 | 50.4 | 56.8 |
| 7 × 7 mm | 92.1 | 7.9 | 72.1 | 66.3 | 71.6 |
| 5 × 5 mm | 95 | 5 | 81.4 | 77.3 | 81.2 |

In an example, the technique provides for a yield calculation for 0.1 defects/cm² verses die size for different redundancy (MWA=10% is high redundancy, and MWA=100% is no redundancy).

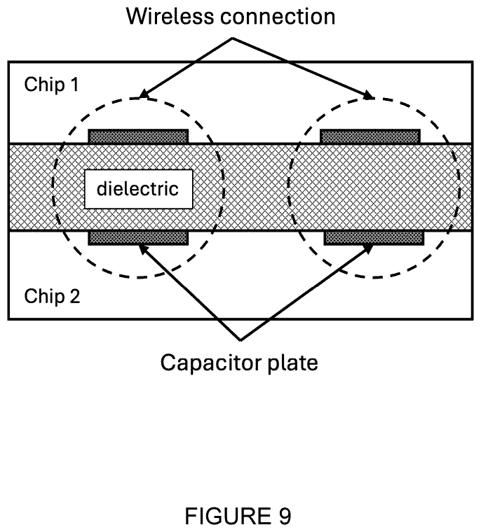

In an example, the present technique includes a capacitive coupling interface on the top die of the N cube chip stack. In an example, chip on wafer hybrid bonding is challenging from throughput and yield due to the small vias which are affected by defects. Stacking ten plus chips would also result in very low yield. Hybrid bonding connecting small via's is challenging for defects. The preparation of chips for hybrid bonding is challenging for defects. Utilizing wireless proximity communication, which relies on capacitive coupling, can be applied in this case to enable efficient data transmission without physical connectors (See, FIG. 9).

The technique is to connect yielding cubes together with capacitive coupling for the signal for a more robust process to create ultra-large stacks. By not using a direct connection for the fin pitch, the process is less sensitive to particles at the interface. The capacitors can be formed on the last steps of the memory or wafer stack formation.

FIG. 9 is a simplified illustration of capacitive coupling that is a non-contact method of data transmission according to an example of the present invention. In an example a high heat conductivity film is added between the layers, capacitive coupling eliminates the need for fine patterning of the signal lines. Examples of high conductivity films like boron nitride, aluminum nitride, and diamond are very hard and difficult to work with using conventional methods.

In an example, the present technique provides for an alternative method for fabrication of very large numbers of vertical chip stacks. In an example, a method to fabricate larger stacks of die is as follows. For the top die in the cubes, capacitors will be fabricated so communications will be via capacitive coupling. This will be done at wafer scale. The method would dice the 4 stack of smaller die (e.g., <100 mm²) and sort for known good cubes. Chip on wafer fusion bonding of one cube to another is included. Non-contact for signaling will make the yield loss per step more robust. There is hybrid bonding, but only for the power TSV's. These will be large diameter structures less sensitive to defects with plenty of redundancy in case there is a bad connection. The method performs other steps, as desired.

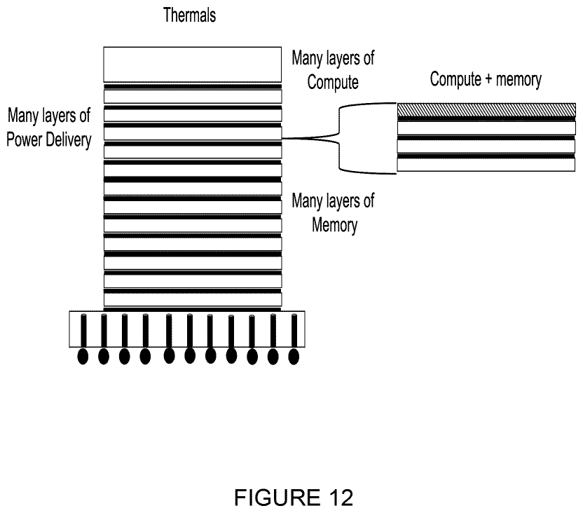

In an example, the present technique provides a cube that is the building block for all compute structures. Scalability of the cube from single cube to whole wafer is enabled with the interposer. The applications range from client to datacenter, and also creation of super HBM stacks. In an example, the cube architecture is flexible. In an example, compute cubes much less than 100 mm² enables a high yielding process that can be attached to a whole wafer with redistribution layers to create a cube network architecture that can be customized for the application (See, FIG. 12).

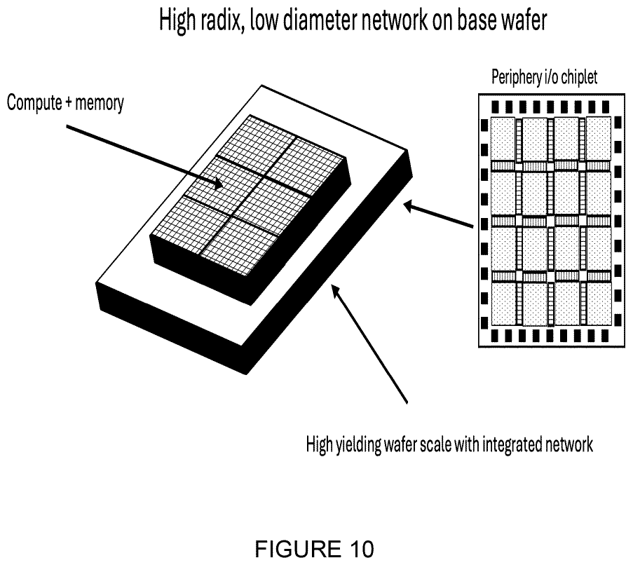

FIG. 10 is a simplified illustration of an example of an interposer with interconnect between dice. In an example, the compute cubes are stacked above the interposer (connecting 16 cubes) to enable large scale compute integration. In an example, the cube architecture can be customized for edge computing applications with a large two-dimensional interposer. If needed, a capping film with high thermal conductivity can be added. (See, FIG. 10).

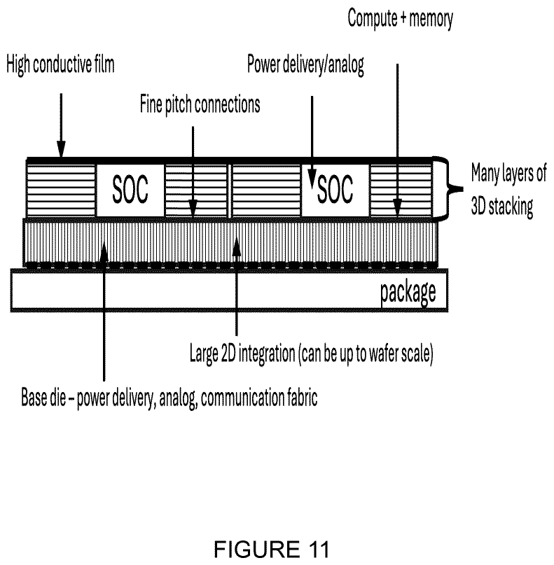

FIG. 11 is a simplified illustration of an example of the use of compute cubes for heterogeneous integration. If a four to five memory stack cube is created and diced, these cubes can be substituted for a single die in the HBM fabrication process. This way, an industry conventional twelve stack can now be a forty stack with significantly higher bandwidth, and lower area penalty (See FIG. 11). In the fabrication process of HBM, current process utilizes bumps and solder. One example would add bumps to both sides of the cube and use the standard fabrication method for HBM which stacks die with thermal compression bonding. Another could utilize the capacitive coupling described previously or hybrid bonding. The goal is for the stacking to be transparent to the HBM process verses single die.

FIG. 12 is a simplified illustration of HBM superstacks by replacing each individual die with a cube of N stacked memory die according to an example of the present invention.

In an example, the present technique is configured to form cubes using a plurality of memory devices. In an example, the present technique can also be configured to combine a logic device or devices with a plurality of memory devices in a cube configuration. Further details of such memory and logic devices can be found throughout the present specification and more particularly below.

In an example, the present invention provides for configuration of central processing units. In an example, the central processing units are foundational components of computing systems, widely recognized for their general-purpose capabilities. These processors are characterized by a configuration comprising one or more cores, caches, and clocking mechanisms designed to execute complex instruction sets efficiently. Their versatility enables application across a broad spectrum of computational tasks, from basic arithmetic operations to sophisticated software execution.

In an example, graphics processing units, in contrast, are specialized for parallel processing and rendering tasks. Distinguished by their architecture comprising thousands of smaller cores, these processors are particularly suited for computations requiring simultaneous processing of multiple data streams. Beyond their traditional role in graphics rendering, they are increasingly employed in artificial intelligence, machine learning, and high-performance scientific applications, owing to their capability to handle large-scale matrix computations.

In an example, tensor processing units represent a class of processors specifically engineered for machine learning workloads. These devices are optimized for tensor operations, which are integral to neural network computations. Their streamlined design enables high-speed execution of matrix multiplications, rendering them highly effective for accelerating deep learning algorithms and other AI applications.

In an example, digital signal processors are designed to efficiently process real-time signal data. These processors excel in manipulating digitized analog signals, such as audio or video data, through dedicated signal processing algorithms. Applications include, but are not limited to, audio compression, video encoding, radar processing, and telecommunications, where their real-time capabilities are particularly advantageous.

In an example, microcontrollers constitute a category of processing devices that integrate a central processing unit, memory, and input/output peripherals on a single chip. These low-power devices are optimized for executing predefined tasks within embedded systems. Applications are diverse, spanning consumer electronics, automotive control systems, industrial machinery, and Internet of Things (IoT) devices.

In an example, field-programmable gate arrays are reconfigurable hardware devices capable of being programmed post-manufacture to perform specific computational tasks. These processors offer a flexible alternative to fixed-function hardware, making them suitable for telecommunications, data processing, and adaptable AI workloads. Their versatility, however, is balanced by relatively lower processing speeds compared to dedicated application-specific integrated circuits.

In an example, application-specific integrated circuits are custom-designed processors optimized for a narrowly defined set of tasks. These processors achieve superior efficiency and reduced power consumption compared to general-purpose processors. They are employed in specialized applications such as cryptocurrency mining and telecommunications infrastructure, where task specificity justifies their fixed functionality.

In an example, neural processing units represent a specialized class of processors designed to execute artificial intelligence and machine learning computations. Found in modern smartphones, edge devices, and other intelligent systems, these processors optimize neural network operations, including real-time image recognition, voice processing, and computational photography.

In an example, vision processing units, embedded processors, and other domain-specific processors further extend the capabilities of semiconductor technology, addressing the specialized needs of industries such as augmented reality, robotics, and industrial automation.

This invention recognizes the importance of these processing devices in enhancing computational efficiency and expanding the capabilities of modern computing systems. Each category of processor is defined by its architectural features and operational efficiencies, which are optimized for specific applications. These advancements collectively represent a contribution to the field of semiconductor technology.

In an example, the present technique can be configured with various types of memory devices utilized in high-speed computing applications, each serving distinct roles based on their architecture and operational characteristics. The memory devices are desirable to achieving the performance, efficiency, and reliability demanded by modern computational systems.

In an example, static random-access memory, or SRAM, is a high-speed, volatile memory type that stores data in flip-flop circuits. Due to its architecture, SRAM does not require periodic refreshing, enabling rapid access times. SRAM is commonly found in processor caches, such as L1, L2, and L3 caches, where latency in the range of nanoseconds is critical. For instance, modern CPUs and GPUs use SRAM-based caches with sizes ranging from a few kilobytes (e.g., 32 KB for L1 caches) to several megabytes (e.g., 128 MB for high-end L3 caches). Variants of SRAM include asynchronous SRAM, used for applications requiring simple and independent operation, and synchronous SRAM (SSRAM), which is clock-synchronized for use in applications such as networking equipment.

In an example, dynamic random-access memory, or DRAM, is another widely used volatile memory type that stores data in capacitors. Unlike SRAM, DRAM requires periodic refreshing due to the charge leakage from the capacitors. Despite slightly slower access times compared to SRAM, DRAM offers significantly higher densities and lower costs. DRAM serves as the main memory in most computing systems, with typical module sizes ranging from 4 GB to 128 GB in consumer devices and up to 6 TB or more in high-performance servers. Examples of DRAM technologies include synchronous DRAM (SDRAM), used in DDR (double data rate) modules such as DDR4 and DDR5, and high-bandwidth memory (HBM), designed for applications requiring massive data transfer rates, such as AI and high-performance computing.

In an example, flash memory is a non-volatile memory type that retains data even when power is removed. Widely used for high-speed read and write operations, flash memory appears in solid-state drives (SSDs), USB drives, and embedded systems. For example, consumer SSDs often use NAND flash with capacities ranging from 256 GB to 4 TB, while enterprise-grade SSDs can exceed 30 TB. Flash memory is further categorized into types such as single-level cell (SLC), multi-level cell (MLC), and triple-level cell (TLC), each offering trade-offs between speed, durability, and density. SLC flash, for instance, is used in applications requiring high durability and speed, such as industrial systems, whereas TLC flash is preferred for cost-effective, high-capacity consumer storage.

In an example, electrically erasable programmable read-only memory, or EEPROM, is another type of non-volatile memory that allows data to be electrically written and erased at the byte level. Although slower than flash memory, EEPROM provides the flexibility to update small amounts of data repeatedly, making it ideal for storing configuration data in embedded systems. Typical EEPROM sizes range from a few kilobytes to a few megabytes, sufficient for tasks such as saving settings in automotive electronics or microcontrollers.

In an example, magneto-resistive random-access memory, or MRAM, is an emerging memory technology that combines the speed of SRAM with the non-volatility of flash. MRAM stores data using magnetic states rather than electric charges, allowing it to retain information without power. Current MRAM devices typically have capacities of a few megabytes to hundreds of megabytes, but ongoing advancements aim to scale this technology for broader applications, such as high-speed buffers in data centers and wearables.

Other advanced memory technologies include phase-change memory (PCM), which uses the transition between amorphous and crystalline states of material to store data, and resistive RAM (ReRAM), which relies on changes in resistance across a dielectric material. These technologies, still in development or early adoption stages, offer non-volatility and fast access times with capacities expected to scale from megabytes to terabytes as they mature.

These various memory devices, spanning from SRAM and DRAM to flash and emerging technologies, are integral to high-speed computing. Their configurations, ranging from kilobytes to terabytes, and their specific attributes allow for optimized performance across diverse applications, from high-performance processors to embedded and portable systems. This invention recognizes the critical role of these memory technologies in advancing the capabilities of modern computing systems.

### REFERENCE

N. Chujo, K. Sakui, S. Sugatani, H. Ryoson, T. Nakamura and T. Ohba, “Bumpless Build Cube (“BBCube”) 3D: Heterogeneous 3D Integration Using WOW and CoW to Provide TB/s Bandwidth with Lowest Bit Access Energy,” 2023 IEEE Symposium on VLSI Technology and Circuits (VLSI Technology and Circuits), Kyoto, Japan, 2023, pp. 1-2, doi: 10.23919/VLSITechnologyandCir57934.2023.10185277. keywords: {Solid modeling; Three-dimensional displays; Power transmission lines; Random access memory; Bandwidth; Cows; Very large scale integration}.

While the above is a full description of the specific examples, various modifications, alternative constructions and equivalents may be used. As an example, the packaged device can include any combination of elements described above, as well as outside of the present specification. In an example, the present technique provides for cubelets that are integrated into a single cube. Additionally, the terms first, second, third, and final do not imply order in one or more of the present examples. Therefore, the above description and illustrations should not be taken as limiting the scope of the present invention which is defined by the appended claims.

1. A semiconductor integrated circuit cube device comprising:
an interposer substrate member comprising a backside and a front side;
a plurality of sub-cube device, each of the sub-cube devices comprising a silicon substrate and a plurality of logic circuits or a plurality of memory circuits, and each of the plurality of sub-cubes being manufactured as a separate device, each of the sub-cube devices comprising a hybrid bondable material, each of the sub-cube devices comprising a plurality of micro TSV structures configured to provide electrical routing through on or more devices in each of the sub-cube devices, each of the plurality of micro-TSV structure having a dimension of about 2 microns and less;
a stacked configuration comprising the plurality of sub-cubes and configured such the hybrid bondable material from an underling sub-cube device is bonded to a side of the silicon substrate of an overlying sub-cube device; and
a bonding region configured between the front side of the interposer substrate and a backside of a bottom sub-cube device.

2. The device of claim 1 wherein the interposer substrate member is active or passive.

3. The device of claim 1 wherein each of the plurality of sub-cube devices has a thickness of 100 microns and less.

4. The device of claim 1 wherein each of the sub-cube devices comprises at least two upper conductive regions, each of the at least two upper conductive regions of each of the sub-cube devices configured for an architecture design of the cube device.

5. The device of claim 1 wherein each of the sub-cube devices comprises at least two upper conductive regions, each of the at least two upper conductive regions of each of the sub-cube devices configured for an architecture design of the cube device, whereupon the architecture design is configured to allow independent communication from a processing device within one or more of the sub-cube devices to each of one of the plurality of memory devices in one or more of the sub-cube devices.

6. The device of claim 1 wherein each of the plurality memory circuits 128 Gbit and greater.

7. The device of claim 1 wherein the plurality of logic circuits comprise a 1000 cores and greater of GPU logic.

8. The device of claim 1 wherein the plurality of logic circuits comprise 5 cores and greater of CPU logic.

9. The device of claim 1 wherein each of the sub-cubes comprises at least 100,000 micro TSVs within one millimeter square or less.

10. The device of claim 1 wherein the bonding region is characterized by a hybrid bond between the interposer substrate and one of the plurality of sub-cube devices.

11. The device of claim 1 wherein each of the sub-cube devices has been tested using a probe card and are categorized as a good device.

12. The device of claim 1 wherein each of the sub-cube device is made using a 50-millimeter square of silicon and less.

13. The device of claim 1 wherein each of the sub-cube devices has been tested using a probe card and are categorized as a good device and provided from a yielded wafer of 80% and greater.

14. The device of claim 1 wherein the plurality of logic devices comprises at least a pair of the plurality of logic devices for redundancy.

15. The device of claim 1 wherein the plurality of memory devices comprises at least ten percent or more of the memory devices for redundancy.

16. The device of claim 1 wherein the interposer substrate comprises a plurality of cube sites for wafer scale processing.

17. The device of claim 1 wherein the interposer substrate comprises a plurality of cube sites for wafer scale processing, and configuring a plurality of cube devices, respectively, for the plurality of cube sites.

18. The device of claim 1 wherein each of the sub-cube devices comprises at least three layers.

19. The device of claim 1 wherein the plurality of sub-cube devices comprises sixteen and greater sub-cube devices.

20. The device of claim 1 wherein each of the sub-cube devices comprises at least four layers and the plurality of sub-cube devices comprises twelve and greater sub-cube devices configured to stack forty-eight separate and independent integrated circuit devices.

21. A method for manufacturing an integrated circuit cube device, the method comprising:
providing a first interposer substrate member comprising a backside and a front side;
bonding a first sub-cube device to the front side of the first interposer substrate from a plurality of sub-cube devices numbered from 1 through N, where Nis an integer greater than 2, the first sub-cube device comprising a first silicon substrate and a plurality of first logic circuits or a plurality of first memory circuits, and the first sub-cube being manufactured as a separate device, the first sub-cube device comprising a first hybrid bondable material, the first sub-cube device comprising a plurality of first micro TSV structures configured to provide electrical routing through on or more devices in the first sub-cube devices, each of the plurality of first micro-TSV structure having a dimension of about 2 microns and less;
providing a second sub-cube device assembled onto a second interposer substrate, the second sub-cube device comprising a second silicon substrate and a plurality of second logic circuits or a plurality of second memory circuits, and the second sub-cube being manufactured as a separate device, the second sub-cube device comprising a second hybrid bondable material, the second sub-cube device comprising a plurality of second micro TSV structures configured to provide electrical routing through on or more devices in the second sub-cube device, each of the plurality of second micro-TSV structure having a dimension of about 2 microns and less;
assembling the second sub-cube device by coupling the second hybrid bondable material of the second sub-cube device to the first hybrid bondable material of the first-cube device;
providing a third sub-cube device assembled onto a third interposer substrate, the third sub-cube device comprising a third silicon substrate and a plurality of third logic circuits or a plurality of third memory circuits, and the third sub-cube being manufactured as a separate device, the third sub-cube device comprising a third hybrid bondable material, the third sub-cube device comprising a plurality of third micro TSV structures configured to provide electrical routing through on or more devices in the third sub-cube device, each of the plurality of third micro-TSV structure having a dimension of about 2 microns and less;
assembling the third sub-cube device by coupling the third hybrid bondable material of the third sub-cube device to the second hybrid bondable material of the second-cube device;
providing an Nth sub-cube device assembled onto an Nth interposer substrate, the Nth sub-cube device comprising an Nth silicon substrate and a plurality of Nth logic circuits or a plurality of Nth memory circuits, and the Nth sub-cube being manufactured as a separate device, the Nth sub-cube device comprising a Nth hybrid bondable material, the Nth sub-cube device comprising a plurality of Nth micro TSV structures configured to provide electrical routing through on or more devices in the Nth sub-cube device, each of the plurality of Nth micro-TSV structure having a dimension of about 2 microns and less;
assembling the Nth sub-cube device by coupling the Nth hybrid bondable material of the Nth sub-cube device to the N−1 hybrid bondable material of the N-cube device; and
forming a thermally conductive material overlying an upper surface of the Nth sub-cube device.

22. The method of claim 21 further comprising subjecting the cube device to thermal treatment.

23. The method of claim 21 further comprising forming an oxide material to fill one or more gaps between a pair of cube devices for mechanical stability.

24. The method of claim 21 further comprising forming an oxide material to fill one or more gaps between a pair of cube devices for mechanical stability; and polishing an upper surface of the oxide material.

25. The method of claim 21 further comprising separating the cube device using an oxygen rich plasma.

26. A method for designing a semiconductor integrated circuit cube device comprising:
providing a target design file associated with an integrated circuit cube device;
configuring the target design file with one or more integrated circuit design files for a plurality of sub-cube device comprising a silicon substrate and a plurality of logic circuits or a plurality of memory circuits, and each of the plurality of sub-cubes being manufactured as a separate device, each of the sub-cube devices comprising a hybrid bondable material, each of the sub-cube devices comprising a plurality of micro TSV structures configured to provide electrical routing through on or more devices in each of the sub-cube devices, each of the plurality of micro-TSV structure having a dimension of about 2 microns and less; and
outputting the target design file configured with the one or more integrated circuit design files to layout the integrated circuit cube device configured in a stacked configuration comprising the plurality of sub-cubes and configured such the hybrid bondable material from an underling sub-cube device is bonded to a backside of the silicon substrate of an overlying sub-cube device.
